(19) United States
(12) Patent Application Publication
(10) Pub. No.: US 2004/0043572 A1
(43) Pub. Date: Mar. 4, 2004

(54) Semiconductor device manufacturing method

(76) Inventors: Naoharu Nishio, Kanagawa (JP); Hiroshi Kitajima, Kanagawa (JP); Tomoko Matsuda, Kanagawa (JP)

Correspondence Address: Darryl G. Walker, WALKER & SAKO, LLP, Suite 235, 300 South First Street, San Jose, CA, 95113, US

(21) Appl. No.: 10/644,247

(22) Filed: Aug. 20, 2003

(30) Foreign Application Priority Data
Aug. 22, 2002 (JP) 2002-241829

(51) Int. Cl. H01L 21/336; H01L 21/425

(52) U.S. Cl. 438/302; 438/525; 438/530

(57) ABSTRACT

An ion implantation method is disclosed which can suppress point defects in a crystal semiconductor material that can arise from ion implantation in a semiconductor device manufacturing process. According to an embodiment, in a semiconductor device manufacturing process, in the place of an ion implantation step of a heavy ion, such as indium (In), in which the channeling phenomenon does not substantially occur in the formation of a pocket diffusion layer region, such a heavy ion can be implanted so that an implant angle (3) becomes 50°±6° with respect to an exposed Si (100) face of an Si (100) substrate (2). Then, implanted ions can be activation with a thermal treatment step to form a pocket diffusion layer region.

### TECHNICAL FIELD

The present invention relates to generally to a semiconductor device manufacturing method, and more particularly to a semiconductor device manufacturing method for insulated field effect transistors that utilizes an ion-implantation step.

### BACKGROUND OF THE INVENTION

For high density integrated circuits that include insulated gate field effect transistors, such as metal-oxide-semiconductor field effect transistors (MOS-FETs), it has been a continuing goal to improve integration density. To achieve greater density, there continue to be ongoing attempts to reduce transistor area, such as by reducing transistor gate length. A reduction in transistor gate length is typically accompanied by necessary reduction in source/drain junction depth. Unfortunately, shallower source/drain junctions can give rise to higher source/drain resistance.

One way to address resistance values for shallow source/drains can be to utilize a high concentration source/drain shallow junction diffusion layer. Such a layer can increase an impurity concentration at a surface of a source/drain junction while decreasing junction depth.

Reductions in gate length can be subject to performance drawbacks. For example, as gate lengths are reduced, resulting transistors can suffer from a rapid decrease in threshold voltage due to punch-through in the channel regions. Such effects are well known as “short gate effects” or “short channel effects”. To address such drawbacks, there is proposed a transistor structure provided with a high concentration type impurity layer (e.g., p-type) that can prevent punch-through. Such an impurity layer is referred to as a “pocket” diffusion layer. A pocket diffusion layer region can have sufficient depth so as to enclose a shallow high concentration source/drain shallow junction diffusion layer of an opposite conductivity (e.g., n-type).

To manufacture an NMOS-FET having such a structure, a negative conductivity type (n-type) impurity high-concentration source/drain shallow junction diffusion layer and a high-concentration positive conductivity type (p-type) impurity diffusion layer are formed according to the conventional ion implantation process set forth below.

The conventional process can include the steps of: forming a gate electrode on a gate insulator that is patterned to correspond to a desired gate length; using the gate electrode as an implantation mask to implant n-type impurities. For example, arsenic (As) is implanted at a high concentration into a silicon (Si) substrate with a low ion implantation acceleration energy. A p-type impurity is also implanted. For example, indium (In) is implanted at an acceleration energy so as to be positioned deeper than a maximum depth of the implanted As. In addition, after a gate sidewall insulation film has been formed on sides of a gate electrode, the gate electrode and gate sidewall insulation film are used as an implantation mask in a self-aligned implant step. For example, phosphorous (P) is implanted separately to a depth of the high concentration p-type impurity diffusion layer. This forms deep junction source and drain diffusion layers. After these ion implantation steps, annealing is performed to activate the implanted ions.

The above annealing step can be a high temperature short-time annealing method, such as a rapid thermal anneal (RTA). An RTA step can suppress thermal diffusion of implanted impurities that accompanies an annealing step, and thereby try maintain as steep an impurity distribution as possible. However, even under high temperature short-time annealing by RTA, if the density of inter-lattice Si atoms and lattice vacancies (e.g., crystal defects) are increased at the time of ion implantation, accelerated diffusion of impurities can occur. As a result, a post-activation impurity distribution can trail a desired distribution shape. Such a phenomenon is referred to as the transitionally accelerated diffusion phenomenon.

Furthermore, as implanted ion area density (e.g., concentration, or dose) increases or acceleration energy increases, the density of inter-lattice Si atoms and lattice vacancies generated at the time of ion implantation can increase correspondingly. For example, in the case of heavy ion implantation species, such as In, the acceleration energy is high in level in order to set an impurity distribution peak at a relatively deep position. As a result, in the vicinity of the distribution peak, a region is formed having a high density of inter-lattice Si atoms and lattice vacancies. If an implantation amount is increased to a much larger level, the atomic structure of the substrate can become amorphous or substantial crystal defects can occur.

When forming an n-type source/drain shallow junction diffusion layer, if an implant angle is selected to be perpendicular to a (001) face of an Si substrate, the “channeling” phenomenon can occur. For example, when As is implanted in high concentration, due to the crystal orientation of the Si substrate, the ratio of impurity ions that penetrate beyond an average range corresponding to the implant energy can be excessive. To avoid spreading an impurity concentration distribution from the channeling phenomenon, an inclination ion implantation method (i.e., a tilt implant) is conventionally employed. In such a method, an implant direction can be at an angle other than perpendicular to the (001) face of the target substrate. When a gate electrode is utilized as an implantation mask, an implant angle is typically selected to be within 30° of the perpendicular, typically about 15°, to prevent an ion implantation region below the gate insulation film from spreading too far. Tilt-angle implantation is typically used with a rotating substrate to achieve in-plane averaging for the implantation results.

It is noted that substrate rotation/inclination ion implantation at an implant angle of 15° is conventionally employed not only in a low acceleration energy ion implantation step (e.g., implantation of As), but also in the other implant steps described above. Such steps include the high concentration implantation of In, used to form a high concentration p-type impurity diffusion layer (the pocket diffusion layer for preventing punch-through), as well as the deep implantation of P, used to form the deep junction source and drain diffusion layers.

The present inventors have found that to further reduce n-type IGFET (e.g., NMOSFET) gate lengths, it can become necessary to make the negative conductivity type high concentration source/drain shallow junction diffusion layer even more shallow, to thereby provide a higher concentration of impurities at the surface. In doing so, it may also be necessary to more effectively suppress the transitionally accelerated diffusion phenomenon that may arise during the implantation of a p-type impurity (e.g., In) utilized in forming a pocket diffusion layer region. That is, it is desirable to arrive at some way of reducing the overall density of inter-lattice Si atoms and/or lattice vacancies that are generated by such a pocket implant step. Such a defect reduction should have essentially no effects on the overall depth-direction of an impurity concentration distribution used to form the pocket diffusion layer region.

In light of the above, it would be desirable to provide a semiconductor device manufacturing method with an ion implantation method that can significantly reduce the density of inter-lattice Si atoms and/or lattice vacancies as compared to conventional tilt angle implantation approaches at 15° or so. Such an approach should have no substantial effects on implantation amounts. Specifically, such an approach should not adversely affect a resulting depth-directional impurity concentration distribution.

### SUMMARY OF THE INVENTION

In order to better understand the various aspects of the present invention, findings by the inventors related to the invention will be briefly discussed.

The present inventors have made considerable investigations into the above conventional three ion implant steps that form the n-type high concentration source/drain shallow junction diffusion layer, the p-type (e.g., pocket) impurity diffusion layer, and the n-type deep junction source/drain diffusion layer. Such investigations have ascribed the adverse effects of inter-lattice Si atoms and lattice vacancies mainly to the step of a high-concentration implant of In, which occurs in the formation of the high concentration p-type (e.g., pocket) impurity diffusion layer. That is, the present inventors have found that if densities of inter-lattice Si atoms and lattice vacancies are high within the high concentration p-type (e.g., pocket) impurity diffusion layer, the phenomenon of a post-activation impurity distribution that trails in a depth direction, ascribed to transitionally accelerated diffusion, becomes more remarkable.

It is known that inter-lattice Si atoms and lattice vacancies can occur when Si atoms are released from a crystal lattice position by an impact of an implanted ion species. The present inventors have found that if an ionic species is implanted in such a direction so as to give rise to the channeling phenomenon, such an implantation step can be effective in suppressing the generation of inter-lattice Si atoms and lattice vacancies. Although, it is understood that such an implantation step results in increased penetration of the species.

It has been found that the above channeling can occur most remarkably in a direction along a (111) or (110) face of a cubic crystal structure, so that selecting either of these two directions can have a significant effect on suppressing the occurrence of inter-lattice Si atoms and lattice vacancies. Furthermore, the present inventors have confirmed that if an ion species is implanted in such a direction so as to give rise to channeling, the penetration range in that direction does increase relatively. However, by selecting a direction giving rise to the channeling phenomenon to have a inclination of about 50° or so, with respect to a (001) face of an Si substrate, a resulting impurity concentration distribution in a direction perpendicular to the surface (i.e., the depth direction), can have a steepness comparable to that resulting from a conventional rotating tilt implant at an angle of about 15° or so. The present invention has arisen based on this knowledge developed by the inventors.

The present invention may include a method for manufacturing a semiconductor device having an insulated gate field effect transistor (IGFET). The method can include a first ion implantation step of implanting at high concentration a first conductivity type impurity to form a first conductivity type high concentration source/drain shallow junction diffusion layer of a source/drain region of the IGFET using a gate electrode of the IGFET as an implant prevention mask. A second ion implantation step, after the first ion implantation step, can include implanting at high concentration a second conductivity type impurity to form a high concentration second conductivity type impurity diffusion layer for the source/drain region of the IGFET using a gate electrode of the IGFET as an implant prevention mask. The acceleration energy for the second conductivity type impurity can be higher than the acceleration energy for the first conductivity type impurity of the first ion implantation step. Further, an implant angle of the second conductivity type impurity with respect to a direction perpendicular to a (001) or equivalent face of a silicon substrate can be in the range of 50°±6°.

According to one aspect of the embodiments, in the second ion implantation step the silicon substrate is rotated while the implant angle is maintained with respect to the substrate.

According to another aspect of the embodiments, the first conductivity type is n-type and the second conductivity type is p-type

According to another aspect of the embodiments, the second conductivity type impurity is a species of indium (In).

According to another aspect of the embodiments, the first conductivity type impurity of the first ion implantation step is a species of arsenic (As).

According to another aspect of the embodiments, the method may further include an annealing step of activating at least the first conductivity type impurity of the first ion implantation step and the second conductivity type impurity.

According to another aspect of the embodiments, the annealing step is a rapid thermal anneal.

According to another aspect of the embodiments, the method may also include a third ion implantation step, after the second ion implantation step, of implanting at high concentration a first conductivity type impurity to form another first conductivity type diffusion layer at a greater depth than the high concentration second conductivity type impurity diffusion layer. In such a step, a gate electrode and sidewalls formed on the sides of the gate electrode of the IGFET can be used as an implant prevention mask.

The present invention may also include a method for manufacturing a semiconductor device having the steps of forming a gate electrode on the surface of a semiconductor material having a cubic crystal structure, and forming at least a portion of a source/drain region by implanting an impurity of a first conductivity type into a semiconductor crystal cubic structure at an inclination angle using the gate electrode as an implant mask. During such an implant step a substrate can be rotated about a rotational axis. The inclination angle can be greater than 15° and less than 80° with respect to a direction perpendicular to the surface, and can result in channeling of the impurity for a majority of directions about the rotating axis.

According to one aspect of the embodiments, the semiconductor crystal cubic structure comprises silicon, and the inclination angle is in the range of 50°±6°.

According to another aspect of the embodiments, the impurity of a first conductivity type has a mass greater than arsenic (As).

According to another aspect of the embodiments, the impurity of a first conductivity type is a p-type impurity having a mass greater than boron (B).

According to another aspect of the embodiments, rotating the substrate about a rotational axis can include a rotation type selected from the group consisting of: continuous rotation and step rotation at predetermined angular intervals.

According to another aspect of the embodiments, the step of forming at least a portion of a source/drain region can include, prior to implanting the impurity of a first conductivity type, implanting an impurity of a second conductivity type with the gate electrode as an implant mask to form a high concentration source/drain shallow junction diffusion layer. Further, implanting the impurity of a first conductivity type forms a pocket implant diffusion region for preventing punch-through in an insulated gate field effect transistor comprising the gate electrode. The method also includes a heat treatment step for activating the impurities of the first and second conductivity type.

The present invention also includes a method of manufacturing a semiconductor device including the steps of: forming gate electrode over a semiconductor substrate; implanting an impurity of a first conductivity type at a first inclination angle with respect to a direction perpendicular to the substrate that avoids substantial channeling through a crystal structure of the semiconductor substrate with the gate electrode as an implant mask. The method may further include implanting an impurity of a second conductivity type at a second inclination angle with respect to a direction perpendicular to the substrate that results in substantial channeling through the crystal structure of the semiconductor substrate with the gate electrode as an implant mask.

According to one aspect of the embodiments, the semiconductor substrate comprises a cubic crystal structure with a (001) or equivalent crystal face exposed to the implanting steps, and the second inclination angle is in the range of 50°±6°.

According to another aspect of the embodiments, the semiconductor substrate comprises a cubic crystal structure with a (001) or equivalent crystal face exposed to the implanting steps, the first inclination angle is in the range of 7-20°, and the second inclination angel is in the range of 38-62°.

According to another aspect of the embodiments, the step of implanting the impurity of the first conductivity type forms a high concentration source/drain shallow junction diffusion layer of a source/drain region. In addition, the step of implanting the impurity of the second conductivity type forms a pocket diffusion region for preventing punch-through of a transistor comprising the source/drain region and gate electrode. The method can also include an annealing step for activating the impurities of the first and second conductivity types.

According to another aspect of the embodiments, the impurity of the second conductivity type can have a mass less than the impurity of the first conductivity type.

According to another aspect of the embodiments, the first conductivity type is n-type, and the impurity of the second conductivity type has mass greater than boron (B).

### BRIEF DESCRIPTION OF THE DRAWINGS

FIG. 1 shows a second ion implantation step in a semiconductor device manufacturing method according to one embodiment of the present invention.

FIG. 2(a) is a cross sectional view showing the implantation of ions at an inclination (tilt) angle according to the step of FIG. 1. FIG. 2(b) is a cross sectional view of a high concentration distribution layer of indium (In) after activation by a thermal treatment according to an embodiment of the present invention.

FIG. 3 is a polar diagram, with a silicon (Si) (001) orientation at center, that shows those orientation at which channeling can occur with high frequency. Imposed on FIG. 3 are orientations of 50°±6° with respect to the Si (001) substrate surface.

FIG. 4 is a graph showing the relationship between concentration of an implanted impurity ion with respect to depth for a depth directional impurity concentration distribution before and after activation by thermal treatment according to one embodiment of the present invention.

FIG. 5(a) is a cross section view showing the implantation of ions at a conventional inclination (tilt) angle of 15°. FIG. 5(b) is cross sectional view of a high concentration distribution layer of indium (In) after activation by a thermal treatment according to the conventional approach of FIG. 5(a).

FIG. 6 is a graph showing the respective depth versus concentration after an In implant thermal treatment for the conventional case.

### DETAILED DESCRIPTION OF THE EMBODIMENTS

Various embodiments of the present invention will now be described in detail with reference to accompanying drawings.

The present invention can include a method for manufacturing a semiconductor device that includes the fabrication of an insulated gate field effect transistor (IGFET), more particularly an n-type metal-oxide-semiconductor FET (n-type MOS-FET or NMOS-FET). Such a method can form an NMOS-FET having an n-type high concentration source/drain shallow junction diffusion layer with a pocket diffusion layer. A pocket diffusion layer can include a high-concentration p-type impurity diffusion layer for punch through prevention for suppressing short channel effects. The method can result in finely patterned MOS-FET devices obtained by reducing a gate length of a MOS-FET on a (001) face of a silicon (Si) substrate.

According to one embodiment, in forming an NMOS-FET, a gate electrode may be patterned on a gate insulator, e.g., gate oxide film. An n-type high concentration source/drain shallow junction diffusion layer can then be formed by implanting ions of an n-type conductivity, e.g. arsenic (As), with a relatively low acceleration energy using the gate electrode as an implant mask. Thus, a peak of an implant As concentration distribution can be formed directly below the surface of the substrate.

Subsequently, ions of a p-type conductivity, e.g. heavy indium (In) ions, can be implanted using a gate electrode as an implant mask. An acceleration energy for such an implant step can be selected so that a peak of an implanted In concentration distribution may be positioned somewhat deeper than a peak of the above-described As concentration distribution. Such a step can form a p-type pocket diffusion layer. Indium (In) can qualify as a pocket diffusion layer implant selection, as its atomic mass is far larger than that of Si. As a result, a resulting concentration distribution with respect to a depth direction can exhibit a steep peak. Further, due to its relatively large atomic mass, In does not have a large diffusion rate in an in-plane direction, relative to other common implant ions. As a result, In has a slower diffusion rate in a lateral direction below the gate oxide film, leading to a better pocket diffusion layer formation.

It will be recalled that in a conventional manufacturing method, the steepness of a depth directional profile can be increased utilizing a tilt implant method. In such a conventional tilt implant, an implant direction is selected to have some inclination with respect to a direction perpendicular to the (001) face of an Si substrate. More particularly, the inclination angle is purposely selected to prevent channeling from occurring in the ion implantation. Specifically, an implantation angle for a In (defined as the angle with respect to a direction perpendicular to the (001) face of the Si substrate) can conventionally be set to 7-15° or so to avoid channeling of the implanted impurities. As a result, a resulting In concentration profile is made steep, and a concentration peak can appear at an average range of In.

In the above conventional implantation approach, however, the occurrence of crystal point defects (e.g., inter-lattice Si atoms and lattice vacancies) can be high in the vicinity of the average range of In. Consequently, in a subsequent thermal activation treatment, acute effects from the accelerated diffusion phenomenon can occur, resulting from the high density of inter-lattice Si atoms and lattice vacancies. Furthermore, after the thermal activation treatment, when high density crystal defects occur, a corresponding pile-up of In can occur. This can give rise to a variations in a concentration distribution that are not reflected in the local maximum position of the concentration profile immediately after implant.

In addition, it will be recalled that As atoms are previously implanted with a relatively low acceleration energy to form an n-type high concentration source/drain shallow junction diffusion layer. Such an implant step can form a peak in the As concentration distribution directly below the substrate surface. The above accelerated diffusion phenomenon, due to the high density of crystal defects generated by the In implantation step, can have a considerable effect on the As concentration distribution.

In sharp contrast, according to the present invention, a pocket type implant (e.g., In) can be performed to produce a steep concentration peak. However, the tilt implant can be selected to have a greater inclination angle (e.g., 50°±6°) with respect to a direction perpendicular to the face of a (001) substrate.

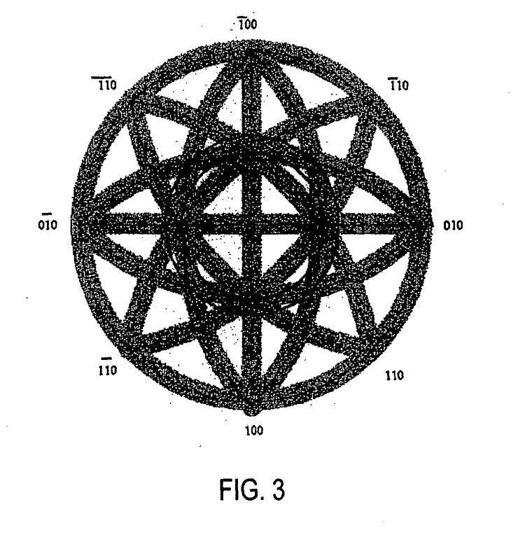

Referring now to FIG. 3, a polar diagram is shown for crystal orientations other than (001). The polar diagram of FIG. 3 shows an Si crystal of a cubic system with a (001) face at the center. That is, if an angle of each crystal orientation with respect to the (001) orientation is given as θ, by plotting tan (θ/2) as a radial variation with respect to a center of (001), the other crystal orientations are indicated. For example, any orientation (k/0) contained in the (001) face perpendicular to the (001) orientation is at angle of 90° with respect to the (001). Thus, for such perpendicular orientations, θ=90° and tan (θ/2)=1. This is reflected by orientations (010), (100) and (110) being positioned on a circumference of a unit circle having (001) as center (the polar diagram of FIG. 3).

In FIG. 3, a crystal orientation parallel to either one of the (111) or (110) faces is indicated by dotted Kikuchi lines. Thus, if ions are implanted in a crystal orientation parallel to either the (111) or (110) faces of the Si crystal, significant channeling occurs. Further, a similar level of channeling also incurs if ions are implanted at an angle of 6° of less with respect to the crossed axes direction. Accordingly, this range is also shown in FIG. 3 by dotted Kikuchi lines.

The implant inclination angle of 50°±6° corresponds to a region in FIG. 3 shown to be sandwiched between concentric circles. One concentric circuit intersects the Kikuchi lines corresponding to the (111) orientation, and shows the orientation of θ=56°. The other concentric circuit intersects the Kikuchi lines corresponding to the (011) orientation, and shows the orientation of θ=44°. As can be understood from this description, a direction having an inclination angle of 50°±6° with respect to a (001) face (i.e., the region within the concentric circles) represents a region that is mostly filled in FIG. 3, thus shows a direction that can give rise to the distinct channeling phenomenon.

If the channeling phenomenon occurs in the implantation of In ions, the ion average range in the crystal increases in the implantation direction, and a resulting distribution width increases correspondingly. It follows, that if an implantation angle is selected to be in the range of 50°±6°, a resulting ion average range will increase. However, when viewed in terms of a distribution in a depth direction from a substrate surface, a resulting concentration distribution can have almost the same peak and almost the same depth directional spread (steepness) as conventional arrangements utilizing implantation angles set to 7-15°.

That is, since In is a heavy ion there is a large difference in ion average range between implantation conditions where channeling occurs, versus conditions where channeling does not occur. However, when the implantation angle is selected to be 50°±6°, this difference (e.g., increase in ion average range) is offset by the inclination angle. Thus, when viewed in terms of a depth direction distribution (i.e., as opposed to total channeling distance), a resulting peak or depth direction spread (steepness) of a resulting concentration profile can be comparable to conventional arrangements utilizing implantation angles set to 7-15°.

In contrast to conventional arrangements (e.g., implant angles of 7-15°) that seek to avoid channeling, under conditions in which channeling occurs, the acceleration energy of implanted ions can be partially consumed by elastic collision with lattice atoms as they travel through an average ion range. Consequently, the frequency of large kinetic In ions within the average range that can release a number of lattice-point Si atoms or give rise to a plurality of lattice vacancies due to chain reaction type collisions, can be greatly reduced, as compared to conventional arrangements in which channeling does not occur in any substantial amount.

Accordingly, in the present invention, by selecting an implant angle of 50°±6°, it is possible to effectively suppress the generation of inter-lattice Si atoms or lattice vacancies, and thereby mitigate the accelerated diffusion phenomenon.

In one particular approach of the present invention, In ions are implanted into a continuously rotating Si (100) substrate under conditions where an implant angle becomes 50°±6°. Thus, conditions are met for the channeling phenomenon to occur.

Alternatively, if step implantation is performed in which a substrate is rotated in increments of 90°, implantation direction can be set to agree with the (1\overline{1}1), (\overline{11}1) and (\overline{1}11) orientations, equivalent to the (111) orientation at θ=56°. In this way, conditions may be correspondingly met for the channeling phenomenon to occur.

Further, if step implantation is performed in which a substrate is rotated in increments of 90°, implantation direction can be set to agree with the (0\overline{1}1), (101) and (\overline{1}01) orientations, equivalent to the (011) orientation at θ=44°. In this way too, conditions can be met for the channeling phenomenon to occur.

Therefore, according to the present invention, ions can be implanted by such implant methods as a rotation inclination (tilt) implant under conditions where an implant angle is 50°±6°, or a rotation inclination (tilt) step implant to rotate a substrate step-wise in increments of a constant angle, in a condition where an Si (100) face is an exposed surface.

By performing rotation inclination (tilt) implant or rotation inclination (tilt) step implant, ion implant concentration in an in-plane direction can be made more uniform. It is noted that if a tilt implant is performed with a gate electrode as an implant mask under conditions for a tilt angle of 50°±6°, and a substrate is not rotated and an implant direction is oriented toward a position below the gate insulation film, a resulting implant ion diffusion layer can be unbalanced. For example, In ions implanted below the gate insulation film can extend from one of a source and drain, but not the other. By rotating a substrate, such deviations are balanced, thereby balancing the amount of ions implanted below a gate insulation film on both sides of a source and drain.

The spread of a resulting profile of an implanted region below a gate insulation film for a tilt angle of 50°±6° can be essentially no different than a convention approach utilizing a tilt angle of 7-15°. Although implanting ions at a higher angle of 50°±6° can increase the spread of an implanted region, such effects are offset by the mitigating effects with respect to the accelerated diffusion phenomenon.

As has been described above, the ion implantation approach of the present invention can perform a tilt implant under conditions where an implant angle can be 50°±6°. The result can have remarkably advantageous effects for those ion implant species that would otherwise result in a high frequency occurrence of inter-lattice Si atoms and lattice vacancies when the channeling phenomenon does not occur. However, the ion implantation approach of the present invention can be applicable to ion species that do not result in a high frequency occurrence of inter-lattice Si atoms and lattice vacancies when the channeling phenomenon does not occur, as the present invention may serve to further reduce the occurrence of inter-lattice Si atoms and lattice vacancies. That is, the present invention can have the advantageous effect to a greater or lesser degree in applications other than an In implant for forming a pocket diffusion layer region.

However, the present invention may have remarkably advantageous effects when utilized in the formation of an insulated gate field effect transistor. In such an application the present invention can include performing an inclination (tilt) implant under the conditions of a tilt angle of 50°±6° to thereby form an insulated gate field effect transistor (IGFET). Such an IGFET can comprise: a gate insulating film; a gate electrode patterned on the gate insulation film, a first conductivity type source/drain region formed in an Si substrate by an ion implantation method.

In such an arrangement, the source/drain region can comprise a structure including at least: a first conductivity type high concentration source/drain shallow junction diffusion layer on a surface; and a punch through prevention high concentration second conductivity type impurity diffusion layer having a depth large enough to enclose the shallow junction diffusion layer.

The present invention may also include a method for manufacturing such a source/drain region. Such a method can comprise at least: a first ion implantation step of implanting a high concentration first conductivity type impurity to form a first conductivity type high concentration source/drain region shallow junction diffusion layer by using a gate electrode as an implant prevention mask; a second ion implantation step of implanting a high concentration second conductivity type impurity to form a high concentration second conductivity type impurity diffusion layer by using a gate electrode as an implant prevention mask; an annealing step of activation the respective two kinds of implant impurities implanted in the first and second ion implantation steps.

In addition, in the above method, the second ion implantation step can be performed after the first ion implantation step. Further, in the second ion implantation step, acceleration energy for the second conductivity type impurity can be set higher than the acceleration energy for the first conductivity type impurity in the first ion implantation step, and an inclination ion implant method can be employed with an inclination angle in the range of 50°±6°. The inclination angle is the implant angle with respect to a direction perpendicular to an (001) face of an Si substrate.

It is understood that a high concentration second conductivity type impurity diffusion layer can be a “pocket” diffusion layer.

A method according to the invention can provide, in addition to the above steps, a third ion implantation step of, after forming a side wall gate insulation film on the side wall of the gate electrode, using the gate electrode and gate side wall insulation film as masks in a self-alignment step to implant a first conductivity type impurity separately to a depth deeper than that of the high concentration second conductivity type diffusion layer. This can form source and drain regions having a deep junction. In this arrangement it is preferable to perform an annealing step to activate implanted impurities after the third ion implantation step is completed.

According to embodiments of the present invention, if an IGFET manufactured is an NMOS-FET, arsenic (As) ions can be implanted as an n-type impurity in a first ion implantation step, indium (In) ions can be implanted as a p-type impurity in a second ion implantation step, and phosphorous (P) ions can be implanted as an n-type impurity in a third ion implantation step. Further, in the case of the first and third ion implantation steps, an implant angle can be set to, for example, 7-15° or so, to implant such ions under the conditions where channeling essentially does not occur.

The following will describe the invention with reference to a specific embodiment. It is noted that the embodiment represents but one example of a best embodiment of the invention, and the invention should not be limited to such an embodiment.

The present embodiment shows the fabrication of an NMOS-FET fabricated on the surface of an Si (100) substrate. The NMOS-FET can suppress short channel effects in a finely patterned MOS-FET having a reduced gate length. In such a structure and method, an inclination (tilt) implant method is used to form a pocket diffusion constituted of a high concentration p-type impurity diffusion layer formed to prevent punch through. In contrast to conventional approaches, when implanting such p-type impurities into, for example, an n-type high concentration source/drain shallow junction diffusion layer, a implant angle can be selected to be in the range of 50°±6° with respect to a direction perpendicular to the substrate.

More particularly, in the embodiment In can be the p-type impurity utilized in the formation of the packet diffusion layer region.

FIG. 3 shows a polar diagram is shown for crystal orientations other than (001). In particular, it will be recalled that the polar diagram shows an Si crystal of a cubic system with a (001) face at the center. That is, if an angle of each crystal orientation with respect to the (001) orientation is given as θ, by plotting tan (θ/2) as a radial variation with respect to a center of (001), the other crystal orientations are indicated. For example, any orientation (k/0) contained in the (001) face perpendicular to the (001) orientation is at angle of 90° with respect to the (001). Thus, for such perpendicular orientations, θ=90° and tan (θ/2)=1. This is reflected by orientations (010), (100) and (110) being positioned on a circumference of a unit circle having (001) as center (the polar diagram of FIG. 3).

It will also be recalled that in FIG. 3, a crystal orientation parallel to either one of the (111) or (110) faces is indicated by dotted Kikuchi lines. Thus, if ions are implanted in a crystal orientation parallel to either the (111) or (110) faces of the Si crystal, significant channeling occurs. Further, a similar level of channeling also incurs if ions are implanted at an angle of 6° of less with respect to the crossed axes direction. Accordingly, this range is also shown in FIG. 3 by dotted Kikuchi lines.

Referring still to FIG. 3, in the case of heavy ions such as In, if an implant direction corresponds to a filled region of FIG. 3, the channeling phenomenon can occur. That is, by having nearly all of the region between the concentric circles filled, when a tilt implant is performed at such angle, channeling is essentially guaranteed to occur through all directions about a rotational axis for the substrate.

Still further, as will be recalled, FIG. 3 includes one circle connecting intersections of Kikuchi lines corresponding to (111) orientation, to thereby provide a representation of θ=56°, and another circle connecting intersections of Kikuchi lines corresponding to (011) orientation, to thereby provide a representation of θ=44°. A region corresponding to the area sandwiched between these two circles, which is mostly filled in FIG. 3, meets the conditions giving rise to the distinct channeling phenomenon.

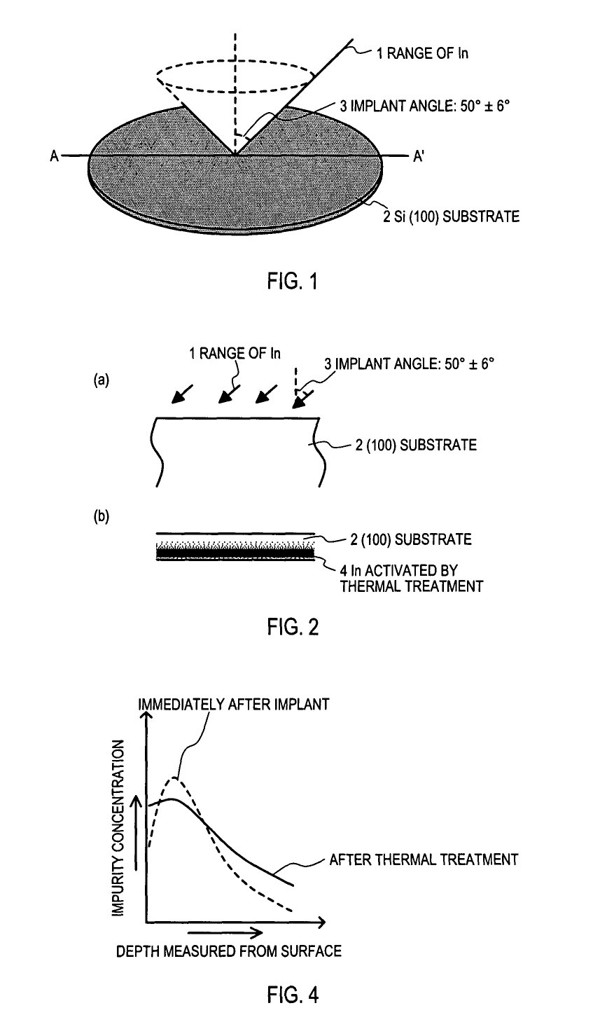

FIG. 1 shows a condition where an ion implant direction can be selected in the region corresponding to the area sandwiched between the two circles described in FIG. 3. Thus, a range 1 in which an implant angle 3 is defined with respect to a normal (vertical direction) of a surface of an Si (100) substrate 2 becomes 44°-56°, that is, a value in the range of 50°±6°.

For example, In ions can be implanted into a continuously rotating Si (100) substrate 2 under conditions in which a range 1 of In can be parallel to an edge of a circular cone having an apex angle of about 110°. Under such conditions, an implant angle becomes about 50°, corresponding the conditions for the occurrence of the channeling phenomenon can be met.

Alternatively, In ions can be implanted into an Si (100) substrate 2 that rotates in increments of 90° so that an ion implant direction may correspond with (1\overline{1}1), (\overline{11}1) and (\overline{1}11) orientations, equivalent to the (111) orientation at θ=56°. Correspondingly the conditions for the occurrence of the channeling phenomenon can be met.

In a similar fashion, a substrate can be rotated in increments of 90°, and an implant direction can be set to correspond to (0\overline{1}1), (101) and (\overline{1}01) orientations, equivalent to the (011) orientation at θ=44°. Again, in this arrangement conditions are met for the channeling phenomenon to occur.

Generally, if ions are injected according to a method that continuously rotates an Si (100) substrate 2, or rotates a substrate in increments of a constant rotation angle under conditions in which the implant angle 3 is maintained in the range of about 50°±6°, balanced ion implantation in an in-plane direction can be accomplished.

If the channeling phenomenon occurs in an In implantation, an average ion range in the implant direction can increase, and a distribution width can increase correspondingly. Thus, if an injection angle is selected in the range of about 50°±6°, ion average range can increase. However, when viewed in terms of a distribution in a depth direction with respect to a substrate surface, an implant concentration can have almost the same peak, and depth directional spread (steepness) as a conventional arrangement. That is, since In is a relatively heavy ion, there is a large difference in average range between a condition in which the channeling phenomenon occurs, and a condition in which the channeling phenomenon does not occur. However, when an implant angle is selected to be in the range of 50°±6°, such a difference in range can be offset by the inclination. Consequently, the difference is not reflected in resulting concentration distribution peak and depth directional spread (steepness) when viewed the depth direction.

Furthermore, in such an implantation step, part of the acceleration energy of implanted ions can be consumed by elastic collisions with lattice atoms as they travel through the ion average range. Thus, the frequency with which large kinetic energy In ions in the average range have sufficient energy to release multiple lattice point atoms or cause multiple lattice vacancies, through a chain reaction manner, can be reduced. As a result, there can be fewer inter-lattice Si atoms and lattice vacancies than the conventional approach that avoids channeling.

The present embodiment has been evaluated for the effect of suppressing the generation of inter-lattice Si atoms or lattice vacancies by selecting an implant angle 3 in the range of 50°±6° and the accompanying mitigation of the accelerated diffusion phenomenon. The evaluation results are set forth below.

As shown in FIG. 2(a), In ions 1 were be implanted into an Si (100) substrate 2 under conditions to provide an implant angle of 50°±6°. An acceleration voltage for the implant was 80 kV and an implant dose was 5×10¹² atoms/cm² or less. In this case, an Si (100) substrate 2 was arranged so that its (100) face was exposed.

Conditions for the evaluation specifically included an In ion implantation step that formed a pocket diffusion layer. In such an arrangement, a gate oxide film is formed, a gate electrode is patterned to etch off the gate oxide film on both sides of the gate electrodes to thereby expose the Si (100) face. In this case, the In ions were injected with a method that includes continuously rotated a substrate, while the above inclination (implant) angle was maintained.

After the above ion implantation step was completed, a thermal activation treatment was conducted using a rapid thermal anneal method. Under these conditions, as shown in FIG. 2(b), a concentration distribution of the activated In can have a single local maximum at a position slightly deeper than the substrate surface, and its tip can exhibit a steep end of range (EOR). A substrate end face, formed by cleaving, was then observed under a transmission electron microscope (TEM). No crystal defects involving the pile-up of In in the vicinity of the EOR was observed.

One example of a measured result that was obtained using second ion mass spectroscopy (SIMS) is shown in FIG. 4. FIG. 4 is a graph showing the respective depth versus concentration after an In implant thermal treatment. As a result of thermal diffusion from the thermal treatment, the peak position after the thermal treatment roughly corresponds to that immediately after the implant, to thereby hold a steep concentration profile, although thermal diffusion is observed in a direction along the surface and into the surface.

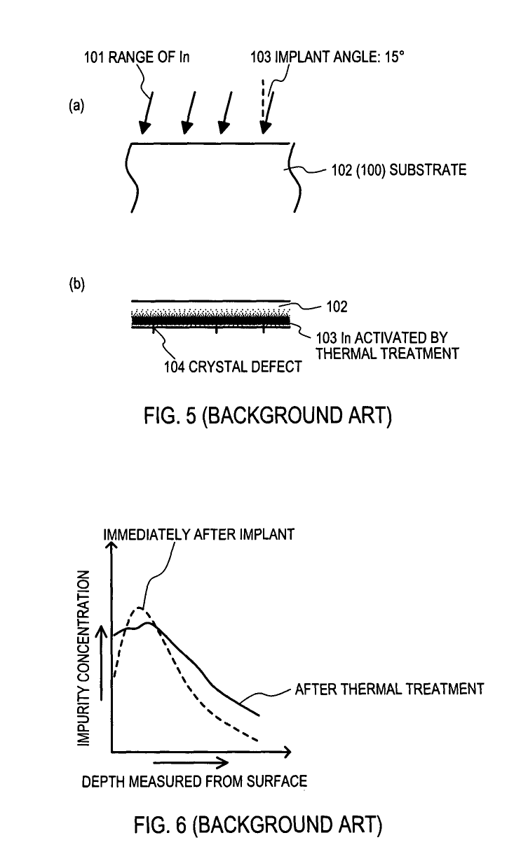

For comparison, the present inventors performed a conventional ion implant method. More specifically, as shown in FIG. 5(a), In ions were implanted at an inclination (tilt) angle 103 of 15° into an Si (100) substrate 103. An acceleration voltage was selected to be 80 kV and the implant dosage was 5×10¹² atoms/cm² or less. In this case, a surface of an Si (100) substrate 102 was arranged so that its (100) face is exposed.

Further, the conditions for the conventional case included an In ion implantation step that formed a pocket diffusion layer. In such an arrangement, a gate oxide film is formed, a gate electrode is patterned to etch off the gate oxide film on both sides of the gate electrodes to thereby expose the Si (100) face. In this case, the In ions were injected with a method that included continuously rotating a substrate, while the above conventional inclination (implant) angle was maintained.

After the above ion implantation step was completed, a thermal activation treatment is conducted using a rapid thermal anneal method. Under these conditions, as shown in FIG. 5(b), a concentration distribution of the activated In had a center at a position slightly deeper than the substrate surface. In the vicinity of an EOR, which is the tip of the In concentration at the time of implant, the formation of crystal defects (e.g., item 104) was present after the thermal treatment. Further, a substrate end face, formed by cleaving, was then observed under a TEM. Such observation revealed In pile-up in the vicinity of the EOR accompanying the formation of the crystal defects.

One example of a measured result that was obtained using SIMS is shown in FIG. 6. FIG. 6 is a graph showing the respective depth versus concentration after an In implant thermal treatment for the conventional case. As a result of thermal diffusion from the thermal treatment, the implanted ions diffused in a direction along the surface and into the surface to form a peak position that more roughly corresponds to that immediately after the implant. Two local maximum positions appear after the thermal treatment.

In addition, FIG. 6 also shows that a diffusion amount in the direction into the substrate is large, thereby showing evidence of the accelerated diffusion phenomenon resulting from the generation of inter-lattice Si atoms and lattice vacancies.

Therefore, in the conventional case, while the concentration profile immediately after ion implantation is steep, corresponding to the case where implanted ions are not subject to the channeling phenomenon, the frequency at which inter-lattice Si atoms and lattice vacancies occurs is high. As a result, the effect of the accelerated diffusion phenomenon during the thermal treatment is considerable. At the same time, pile-up of In ions also occurs. The final depth direction In concentration profile after thermal treatment, as shown in FIG. 6, exhibits significant damage to the steepness of the original concentration profile.

Thus, the conventional result shown in FIG. 6 to the accelerated diffusion phenomenon.

The semiconductor device manufacturing method according the invention can be directed to manufacturing an IGFET having a gate insulating film, a gate electrode patterned on the gate insulation film, a first conductivity type source/drain region formed in an Si substrate by ion implantation.

In such an arrangement, the source/drain region has a structure that includes: at least a first conductivity type high concentration source/drain shallow junction diffusion layer on a surface; a pocket diffusion layer region constituting a punch through prevention high concentration second conductivity type impurity diffusion layer, the pocket diffusion layer having a depth large enough to enclose the shallow junction diffusion layer.

Further, the semiconductor device manufacturing method can include: at least a first ion implantation step of implanting a high concentration first conductivity type impurity to form a first conductivity type high concentration source/drain region shallow junction diffusion layer by using a gate electrode as an implant prevention mask; a second ion implantation step of implanting a high concentration second conductivity type impurity to form a high concentration second conductivity type impurity diffusion layer by using a gate electrode as an implant prevention mask; and an annealing step of activating the respective two kinds of implant impurities implanted in the first and second ion implantation steps.

Still further, in the semiconductor device manufacturing method, an inclination (tilt) implant method is employed by which an inclination ion implant method is performed at an inclination angle in the range of 50°±6°, the inclination angle being the implant angle with respect to a direction perpendicular to an (001) face of an Si substrate. As a result, it can be possible to greatly reduce the density of crystal defects in an EOR region caused by the above second ion implantation step, as compared to conventional methods. In addition, it is also possible to effectively suppress the accelerated diffusion phenomenon caused by a high density of inter-lattice Si atoms and lattice vacancies, which occur from such implant damage. Further, it is also possible to effectively reduce or eliminate unnecessary crystal defects present after a low temperature heating process of the annealing step.

Finally, it is understood that while the various embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A method for manufacturing a semiconductor device having an insulated gate field effect transistor (IGFET), comprising:
a first ion implantation step of implanting a first conductivity type impurity to form a first conductivity type high concentration source/drain shallow junction diffusion layer of a source/drain region of the IGFET using a gate electrode of the IGFET as an implant prevention mask; and
a second ion implantation step, after the first ion implantation step, of implanting a second conductivity type impurity to form a high concentration second conductivity type impurity diffusion layer for the source/drain region using the gate electrode as an implant prevention mask; wherein
the acceleration energy for the second conductivity type impurity is higher than the acceleration energy for the first conductivity type impurity of the first ion implantation step; and
an implant angle of the second conductivity type impurity with respect to a direction perpendicular to a (001) or equivalent face of a silicon substrate is in the range of 50°±6°.

2. The method of claim 1, wherein:
in the second ion implantation step, the silicon substrate is rotated while the implant angle is maintained with respect to the substrate.

3. The method of claim 1, wherein:
the first conductivity type is n-type and the second conductivity type is p-type

4. The method of claim 3, wherein:
the second conductivity type impurity is an indium (In) species.

5. The method of claim 3 wherein:
the first conductivity type impurity of the first ion implantation step is an arsenic (As) species.

6. The method of claim 1, further including:
an annealing step of activating at least the first conductivity type impurity of the first ion implantation step and the second conductivity type impurity.

7. The method of claim 6, wherein:
the annealing step is a rapid thermal anneal.

8. The method of claim 1, further including:
a third ion implantation step, after the second ion implantation step, of implanting a first conductivity type impurity to form another first conductivity type diffusion layer at a greater depth than the high concentration second conductivity type impurity diffusion layer using the gate electrode and sidewalls formed on the sides of the gate electrode, as an implant prevention mask.

9. A method for manufacturing a semiconductor device, comprising the steps of:
forming a gate electrode on the surface of a semiconductor material having a cubic crystal structure; and
forming at least a portion of a source/drain region by implanting an impurity of a first conductivity type into a semiconductor crystal cubic structure at an inclination angle using the gate electrode as an implant mask while rotating the substrate about a rotational axis, wherein
the inclination angle is greater than 15° and less than 80° with respect to a direction perpendicular to the surface, and results in channeling of the impurity for a majority of directions about the rotating axis.

10. The method of claim 9, wherein:
the semiconductor crystal cubic structure comprises silicon; and
the inclination angle is in the range of 50°±6°.

11. The method of claim 9, wherein:
the impurity of a first conductivity type has a mass greater than arsenic (As).

12. The method of claim 9, wherein:
the impurity of a first conductivity type is a p-type impurity having a mass greater than boron (B).

13. The method of claim 9, wherein:
rotating the substrate about a rotational axis includes a rotation type selected from the group consisting of: continuous rotation and step rotation at predetermined angular intervals.

14. The method of claim 9, further including:
the step of forming at least a portion of a source/drain region includes,
prior to implanting the impurity of a first conductivity type, implanting an impurity of a second conductivity type with the gate electrode as an implant mask to form a high concentration source/drain shallow junction diffusion layer,
implanting the impurity of a first conductivity type forms a pocket implant diffusion region for preventing punch-through in an insulated gate field effect transistor comprising the gate electrode, and
a heat treatment step for activating the impurities of the first and second conductivity type.

15. The method of manufacturing a semiconductor device, comprising:
forming a gate electrode over a semiconductor substrate;
implanting an impurity of a first conductivity type at a first inclination angle with respect to a direction perpendicular to the substrate that avoids substantial channeling through a crystal structure of the semiconductor substrate with the gate electrode as an implant mask; and
implanting an impurity of a second conductivity type at a second inclination angle with respect to a direction perpendicular to the substrate that results in substantial channeling through the crystal structure of the semiconductor substrate with the gate electrode as an implant mask.

16. The method of claim 15, wherein:
the semiconductor substrate comprises a cubic crystal structure with a (001) or equivalent crystal face exposed to the implanting steps; and
the second inclination angle is in the range of 50°±6°.

17. The method of claim 15, wherein:
the semiconductor substrate comprises a cubic crystal structure with a (001) or equivalent crystal face exposed to the implanting steps;
the first inclination angle is in the range of 7-20°; and
the second inclination angle is in the range of 38-62°.

18. The method of claim 15, further including:
the step of implanting the impurity of the first conductivity type forms a high concentration source/drain shallow junction diffusion layer of a source/drain region;
the step of implanting the impurity of the second conductivity type forms a pocket diffusion region for preventing punch-through of a transistor comprising the source/drain region and gate electrode; and
an annealing step for activating the impurities of the first and second conductivity types.

19. The method of claim 15, wherein:
the impurity of the second conductivity type has a mass less than the impurity of the first conductivity type.

20. The method of claim 19, wherein:
the first conductivity type is n-type; and
the impurity of the second conductivity type has mass greater than boron (B).
